(19) United States
(12) Patent Application Publication
(10) Pub. No.: US 2025/0006840 A1
(43) Pub. Date: Jan. 2, 2025

(54) NEGATIVE CAPACITANCE FIELD EFFECT TRANSISTOR (NCFET) DEVICES

(71) Applicant: INTEL CORPORATION, SANTA CLARA, CA (US)

(72) Inventors: Rachel A. Steinhardt, Beaverton, OR (US); Kevin P. O'Brien, Portland, OR (US); Dmitri Evgenievich Nikonov, Beaverton, OR (US); John J. Plombon, Portland, OR (US); Tristan A. Tronic, Aloha, OR (US); Ian Alexander Young, Olympia, WA (US); Matthew V. Metz, Portland, OR (US); Marko Radosavljevic, Portland, OR (US); Carly Rogan, North Plains, OR (US); Brandon Holybee, Portland, OR (US); Raseong Kim, Portland, OR (US); Punyashloka Debashis, Hillsboro, OR (US); Dominique A. Adams, Portland, OR (US); I-Cheng Tung, Hillsboro, OR (US); Arnab Sen Gupta, Hillsboro, OR (US); Gauri Auluck, Hillsboro, OR (US); Scott B. Clendenning, Portland, OR (US); Pratyush P. Buragohain, Hillsboro, OR (US); Hai Li, Portland, OR (US)

(73) Assignee: INTEL CORPORATION, SANTA CLARA, CA (US)

(21) Appl. No.: 18/344,022

(22) Filed: Jun. 29, 2023

(51) Int. Cl. H01L 29/78; H01L 29/76; H01L 29/786

(52) U.S. Cl. CPC H01L 29/78391; H01L 29/7606; H01L 29/7869

(57) ABSTRACT

In one embodiment, a negative capacitance transistor device includes a perovskite semiconductor material layer with first and second perovskite conductors on opposite ends of the perovskite semiconductor material layer. The device further includes a dielectric material layer on the perovskite semiconductor material layer between the first and second perovskite conductors, a perovskite ferroelectric material layer on the dielectric material layer, and a third perovskite conductor on the perovskite ferroelectric material layer.

### BACKGROUND

As computing demand increases, the corresponding energy demands of the compute resources increase exponentially. Compute limitations may thus be defined not by the speed of operation, but by the energy needed for operation. To lower energy consumption in compute devices, transistor devices can be designed to use lower operating voltages. However, conventional metal oxide semiconductor field-effect transistor (MOSFET) devices encounter limits on their operating voltage, with their threshold voltage and subthreshold slope dictating the ability to lower currents in the off-state.

### BRIEF DESCRIPTION OF THE DRAWINGS

FIG. 1 illustrates an example negative capacitance field-effect transistor (NCFET) device comprising perovskite materials in accordance with embodiments herein.

FIG. 2 illustrates another example NCFET device comprising perovskite materials in accordance with embodiments herein.

FIG. 3 illustrates an example NCFET device comprising a two-dimensional transition metal dichalcogenide (2D TMD) channel material in accordance with embodiments herein.

FIG. 4 illustrates another example NCFET device comprising a two-dimensional transition metal dichalcogenide (2D TMD) channel material in accordance with embodiments herein.

FIG. 5 is a top view of a wafer and dies that may incorporate any of the embodiments disclosed herein.

FIG. 6 is a cross-sectional side view of an integrated circuit device that may incorporate any of the embodiments disclosed herein.

FIG. 7 is a cross-sectional side view of an integrated circuit device assembly that may include any of the embodiments disclosed herein.

FIG. 8 is a block diagram of an example electrical device that may include any of the embodiments disclosed herein.

### DETAILED DESCRIPTION

Embodiments herein describe transistor devices that operate based on negative capacitance. For example, some embodiments provide negative capacitance field-effect transistor (NCFET) devices that are implemented entirely with perovskite materials. As used herein, a perovskite material may be a material with a crystal structure, with constituent elements ABX₃, where A and B are cations and X is an anion that bonds to the cations, similar to CaTiO₃. Example perovskite materials that can be used herein are described further below.

Other embodiments provide NCFET devices that include a two-dimensional transition metal dichalcogenide (2D TMD) channel material and a perovskite ferroelectric material (e.g., Barium titanate (BTO, BaTiO₃)). Certain embodiments described herein may have steep slopes, and thus, low switching voltages as compared with Silicon-based NCFETs. As an example, some embodiments may have switching voltages of less than 0.2V, as compared with ˜1V for current low switching voltage FET devices. Lower switching voltages in the NCFET can translate into substantial power savings for an integrated circuit device that implements such devices. Furthermore, certain embodiments may be used to implement a large memory array (e.g., a 1 TB memory array).

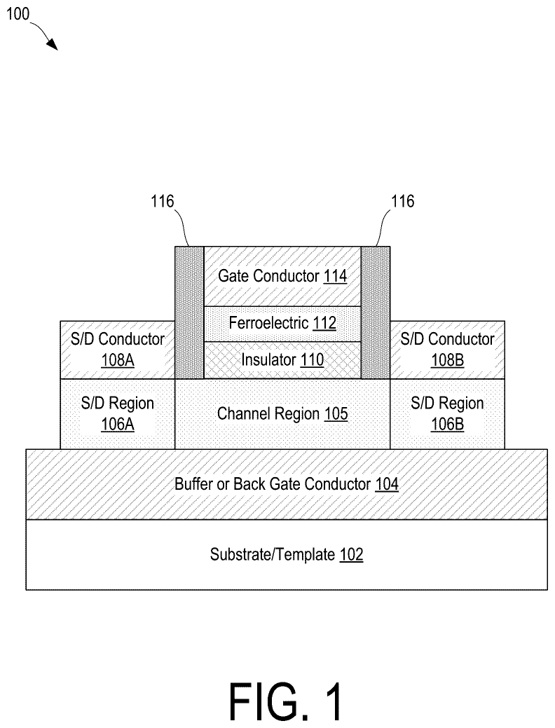

FIG. 1 illustrates an example negative capacitance field-effect transistor (NCFET) device 100 comprising perovskite materials in accordance with embodiments herein. The example device 100 includes a substrate/template layer 102 on which the perovskite materials of the device may be grown or otherwise deposited. In some embodiments, the substrate 102 may include an oxide template material on top of a more typical substrate material. For example, the substrate 102 may include an oxide material layer such as SrTiO₃ (which may also be referred to herein as “STO”) on a silicon-based (e.g., SiO₂) or similar type of substrate material. The device 100 further includes a layer 104, which can be implemented as a buffer layer in some embodiments or as a back gate layer in other embodiments. If implemented as a buffer layer, the layer 104 may include a high-k dielectric material. However, if implemented as a back gate conductor, the layer 104 may be formed from or include SrRuO₃ (which may also be referred to herein as “SRO”), (Sr—Ba) RuO₃, SrIrO₃. (La—Ba) SnO₃, (La—Sr) MnO₃, (La—Ba) CoO₃, LaNiO₃, LaRuO₃, SrVO₃, SrCoO₃, SrMoO₃, or YBa₂Cu₃O₇.

On the layer 104, a channel region 105 and source/drain regions 106 are formed. The channel region 105 may be formed of or include doped perovskite semiconductor materials, e.g., doped BaSnO₃, doped (Ba—Sr) SnO₃, or doped SrTiO₃. The channel region may be doped with Lanthanum (La) or other dopants such as Neodymium (Nd), Caesium (Cs), Yttrium (Y), or Vanadium (V). As used herein, (A-B) (e.g., Ba—Sr) may refer to elements A and B in proportions AₓB₍₁₋ₓ₎ (e.g., BaₓSr₍₁₋ₓ₎SnO₃). The source/drain regions 106 may be formed of or include a doped perovskite material, which may be the same material as the channel region 105 but with higher doping (e.g., between 5-20% doping). There are also source/drain conductors 108 over each respective source/drain region 106. The source/drain conductors 108 may be formed of or include the same materials described above with respect to a back gate layer for layer 104.

The device 100 further includes an insulator layer 110 on the channel region 105, a ferroelectric material layer 112 on the insulator layer 110, and a gate conductor layer 114 on the ferroelectric material layer 112. There is also spacer material 116 between the source/drain conductors 108 and the stack that includes the insulator layer 110, ferroelectric material layer 112, and gate conductor layer 114. The insulator layer 110 may be formed of or include BaSnO₃, SrSnO₃, SrTiO₃, LaALO₃, BaHfO₃, BaZrO₃, SrZrO₃, SrHfO₃, LaInO₃, LaScO₃, LaLuO₃, La(Lu—Sc)O₃, or ReScO₃. The ferroelectric material layer 112 may be formed of or include BaTiO₃ (which may also be referred to herein as “BTO”), Ba(Zr—Ti)O₃, (Ba—Ca)TiO₃, (Ba—Sr)TiO₃, (Ba—Ca)(Ti—Zr)O₃, Ba(Hf—Ti)O₃, BiFcO₃. (Bi—La)FcO₃, Bi(Fe—Co)O₃, LiNbO₃, KNbO₃, GdFeO₃, or (Gd—La)FeO₃. The gate conductor layer 114 may be formed of or include the same materials described above with respect to a back gate layer for layer 104. The spacer material 116 may be a dielectric material, and in certain embodiments, may include SiN₃ or amorphous BN₃.

The use of a perovskite material for the channel in the device 100 may allow for precise layer interfaces, as compared with a Si-based material. Moreover, matching the capacitances of the insulator layer and the ferroelectric material layer may improve this effect. For example, if BTO is used as the ferroelectric material layer, then STO or (Ba—Sr)TiO₃ may be used for the insulator layer as they have a similar capacitance as BTO.

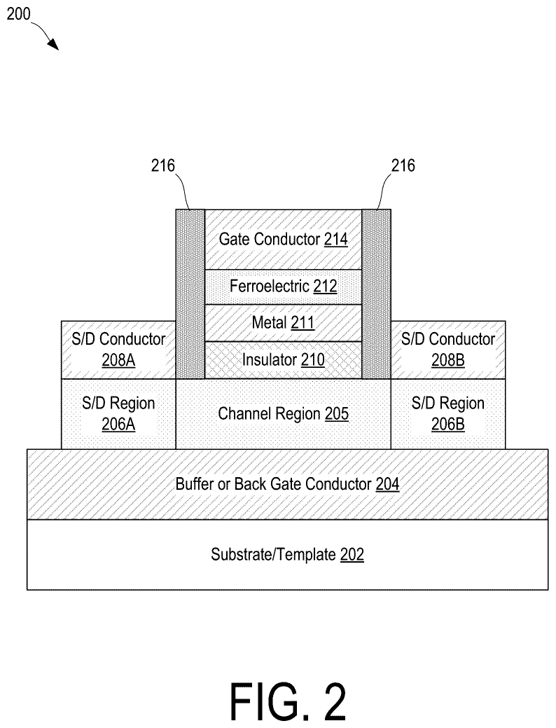

FIG. 2 illustrates another example NCFET device 200 comprising perovskite materials in accordance with embodiments herein. The example device 200 is implemented in a similar manner as the device 100 of FIG. 1; however, the device 200 includes another conductive layer 211 between the insulator layer 210 and ferroelectric material layer 212. The conductive layer 211 may be formed from the same or similar materials as described above with respect to the gate and source/drain conductors. The additional conductive layer 211 can allow for tuning of the phase and strain of the ferroelectric material layer 212, which can offer paths to further decrease the switching voltage of the device 200 (e.g., as compared to the device 100 without the layer 211).

All other layers may be implemented in the same or similar manner as the corresponding material layers of the device 100 as described above. That is, the substrate/template layer 202 may be implemented in the same or similar manner as the substrate/template layer 102, the layer 204 may be implemented in the same or similar manner as the layer 104, the channel region 205 may be implemented in the same or similar manner as the channel region 105, the source/drain regions 206 may be implemented in the same or similar manner as the source/drain regions 106, the source/drain conductors 208 may be implemented in the same or similar manner as the source/drain conductors 108, the insulator layer 210 may be implemented in the same or similar manner as the insulator layer 110, the ferroelectric material layer 212 may be implemented in the same or similar manner as the ferroelectric material layer 112, the gate conductor layer 214 may be implemented in the same or similar manner as the gate conductor layer 114, and the space material layer 216 may be implemented in the same or similar manner as the space material layer 116.

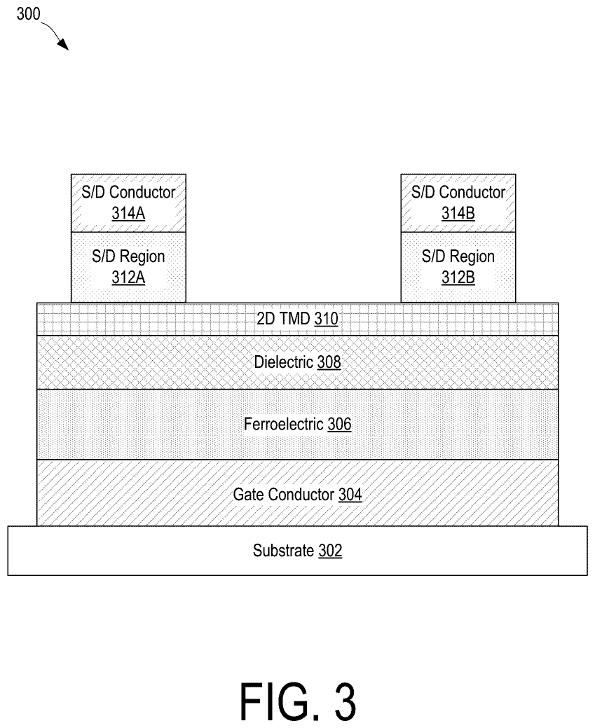

FIG. 3 illustrates an example NCFET device 300 comprising a two-dimensional transition metal dichalcogenide (2D TMD) channel material in accordance with embodiments herein. The example device 300 includes a substrate 302, a gate conductor layer 304 on the substrate 302, a ferroelectric material layer 306 on the gate conductor layer 304, a dielectric layer 308 on the ferroelectric material layer 306, a 2D TMD material layer 310 on the ferroelectric material layer 308, two source/drain regions 312 on the 2D TMD material layer 310, and a source/drain conductor layer 314A. 314B on each respective source/drain region 312A, 312B.

The substrate 302 may be implemented similar to the substrate 102 described above. The gate conductor 304 and source/drain conductors 314 may be implemented with any suitable metal. Some embodiments, for example, may use perovskite materials, such as, for example, SrRuO₃ (SRO), (Sr—Ba) RuO₃, SrIrO₃, (La—Ba) SnO₃, (La—Sr) MnO₃, (La—Ba) CoO₃, LaNiO₃, LaRuO₃, SrVO₃, SrCoO₃, SrMoO₃, or YBa₂Cu₃O₇. The ferroelectric material layer 306 may be implemented with any suitable ferroelectric material. In some embodiments, the layer 306 may be formed of or include a perovskite material, such as, for example, BaTiO₃ (BTO), Ba(Zr—Ti)O₃, (Ba—Ca)TiO₃, (Ba—Sr)TiO₃, (Ba—Ca)(Ti—Zr)O₃, Ba(Hf—Ti)O₃, BiFeO₃, (Bi—La)FeO₃, Bi(Fe—Co)O₃, LiNbO₃, KNbO₃, GdFeO₃, or (Gd—La)FeO₃. The dielectric layer 308 may be implemented with any suitable high-k dielectric material, such as, for example, Tantalum Oxide (Ta₂O₅), Hafnium Oxide (HfO₂), MgO, Al₂O₃, Germanium Oxide (GeO₂).

The 2D TMD material layer 310 may be formed from or include a reduced symmetry material, such as, for example, MoS₂ (Molybdenum disulfide), WS₂ (Tungsten disulfide), WSc₂ (Tungsten diselenide), WTe₂ (Tungsten telluride), NbSe₂ (Niobium diselenide) or MoTe₂ (Molybdenum telluride). Other 2D materials may also be utilized where reduced symmetry in the crystal allows for spin-charge interconversion not requiring to satisfy a right triplet. As used herein, a reduced symmetry material may refer to a material that does not have full mirror symmetry in all of its axes of its crystal structure. That is, the material does not have mirror symmetry in at least one axis of its crystal axes. Reduced symmetry materials that may be implemented herein may include one material (e.g., the TMD materials described previously) or can be a heterostructure comprising two reduced symmetry materials, one full symmetry material (e.g., graphene) and one reduced symmetry material in a stack, or two full symmetry materials that, when stacked, lead to a reduction in symmetry.

The source/drain regions 312 may be formed from or include a perovskite semiconductor material. For example, in some embodiments, the source/drain regions 312 may include doped BaSnO₃, doped (Ba—Sr)SnO₃, or doped SrTiO₃. The source/drain regions 312 may be doped with La or other suitable dopants, e.g., Neodymium (Nd), Caesium (Cs), Yttrium (Y), or Vanadium (V), in particular embodiments. In some embodiments, the source/drain regions 312 may be formed from a 2D TMD material, such as those described above. In such embodiments, the conductors 314 may be doped 2D TMD materials. For example, where WSe₂ is used for the source/drain regions, Nb-doped WSe₂ may be used for the conductors 314. Similarly, where MoS₂ is used for the source/drain regions, Y-doped MoS₂ may be used for the conductors 314. The conductors 314 may also be formed with one of Ru, Au, Pt, Sb, Bi in certain embodiments.

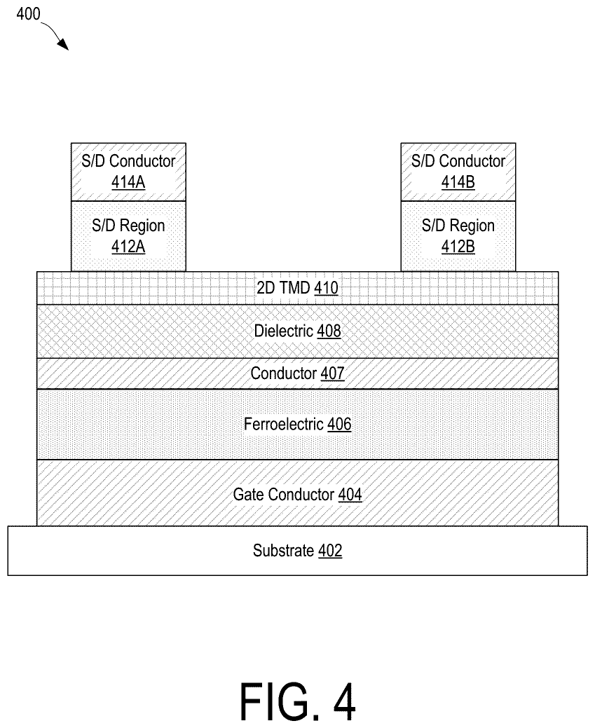

FIG. 4 illustrates another example NCFET device 400 comprising a two-dimensional transition metal dichalcogenide (2D TMD) channel material in accordance with embodiments herein. The example device 400 is implemented in a similar manner as the device 300 of FIG. 3; however, the device 400 includes an additional conductor layer 407 between the ferroelectric material layer 406 and the dielectric layer 408. The additional conductive layer 407 can allow for tuning of the phase and strain of the ferroelectric material layer 406, which can offer paths to further decrease the switching voltage of the device 400 (e.g., as compared to the device 300 without the additional layer 407).

All other layers may be implemented in the same or similar manner as the corresponding material layers of the device 300 as described above. That is, the substrate 402 may be implemented in the same or similar manner as the substrate 302, the gate conductor 404 may be implemented in the same or similar manner as the gate conductor 304, the ferroelectric material layer 406 may be implemented in the same or similar manner as the ferroelectric material layer 306, the dielectric layer 408 may be implemented in the same or similar manner as the dielectric layer 308, the 2D TMD layer 410 may be implemented in the same or similar manner as the 2D TMD layer 310, the source/drain regions 412 may be implemented in the same or similar manner as the source/drain regions 312, and the source/drain conductors 414 may be implemented in the same or similar manner as the source/drain conductors 314.

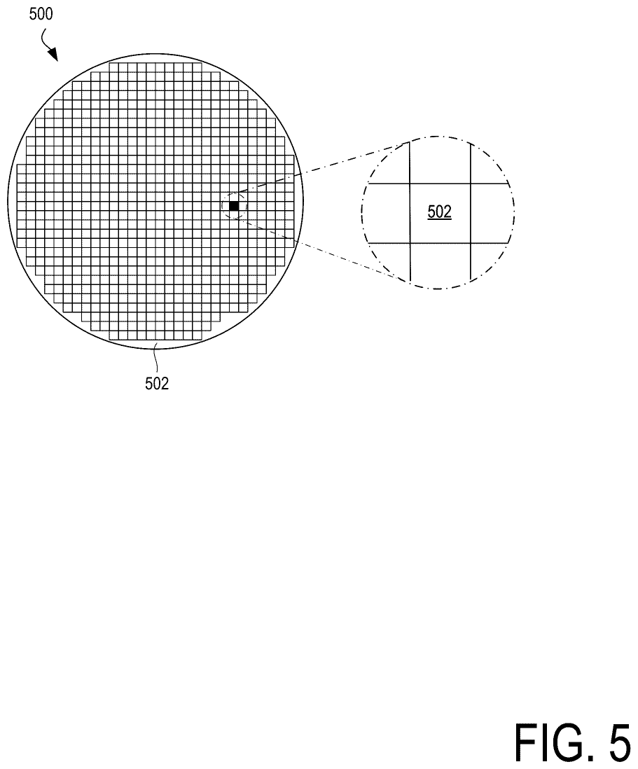

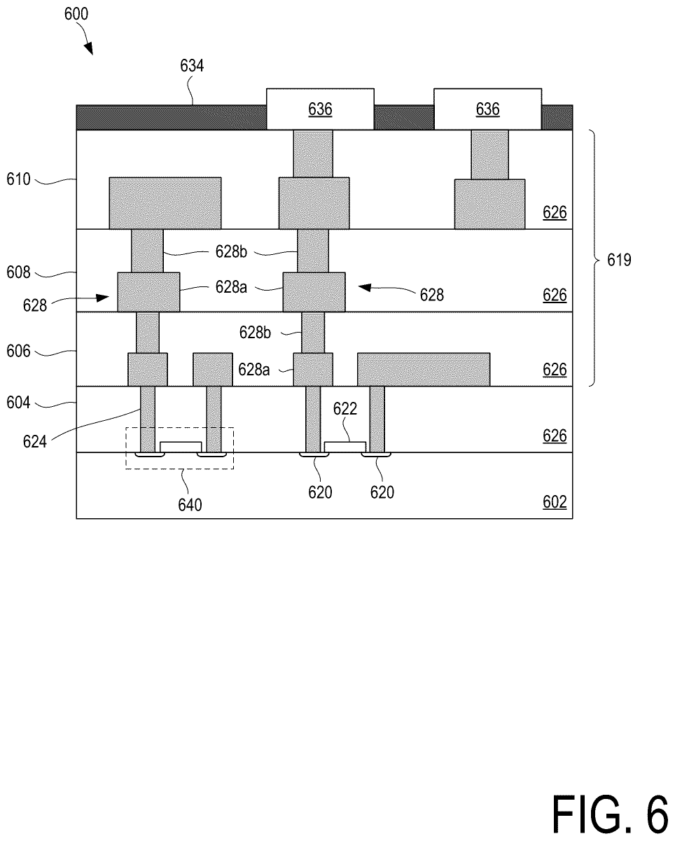

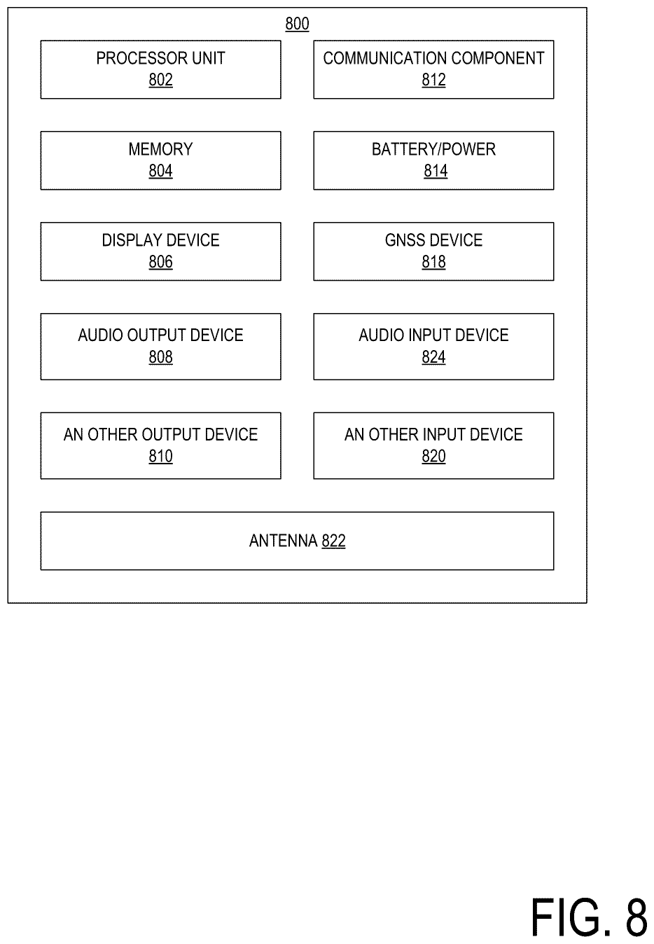

FIG. 5 is a top view of a wafer 500 and dies 502 that may incorporate any of the embodiments disclosed herein. The wafer 500 may be composed of semiconductor material and may include one or more dies 502 having integrated circuit structures formed on a surface of the wafer 500. The individual dies 502 may be a repeating unit of an integrated circuit product that includes any suitable integrated circuit. After the fabrication of the semiconductor product is complete, the wafer 500 may undergo a singulation process in which the dies 502 are separated from one another to provide discrete “chips” of the integrated circuit product. The die 502 may include one or more transistors (e.g., some of the transistors 640 of FIG. 6, discussed below), supporting circuitry to route electrical signals to the transistors, passive components (e.g., signal traces, resistors, capacitors, or inductors), and/or any other integrated circuit components. In some embodiments, the wafer 500 or the die 502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 502. For example, a memory array formed by multiple memory devices may be formed on a same die 502 as a processor unit (e.g., the processor unit 802 of FIG. 8) or other logic that is configured to store information in the memory devices or execute instructions stored in the memory array.

FIG. 6 is a cross-sectional side view of an integrated circuit device 600 that may be included in any of the embodiments disclosed herein. One or more of the integrated circuit devices 600 may be included in one or more dies 502 (FIG. 5). The integrated circuit device 600 may be formed on a die substrate 602 (e.g., the wafer 500 of FIG. 5) and may be included in a die (e.g., the die 502 of FIG. 5). The die substrate 602 may be a semiconductor substrate composed of semiconductor material systems including, for example, n-type or p-type materials systems (or a combination of both). The die substrate 602 may include, for example, a crystalline substrate formed using a bulk silicon or a silicon-on-insulator (SOI) substructure. In some embodiments, the die substrate 602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 602. Although a few examples of materials from which the die substrate 602 may be formed are described here, any material that may serve as a foundation for an integrated circuit device 600 may be used. The die substrate 602 may be part of a singulated die (e.g., the dies 502 of FIG. 5) or a wafer (e.g., the wafer 500 of FIG. 5).

The integrated circuit device 600 may include one or more device layers 604 disposed on the die substrate 602. The device layer 604 may include features of one or more transistors 640 (e.g., metal oxide semiconductor field-effect transistors (MOSFETs)) formed on the die substrate 602. The transistors 640 may include, for example, one or more source and/or drain (S/D) regions 620, a gate 622 to control current flow between the S/D regions 620, and one or more S/D contacts 624 to route electrical signals to/from the S/D regions 620. The transistors 640 may include additional features not depicted for the sake of clarity, such as device isolation regions, gate contacts, and the like. The transistors 640 are not limited to the type and configuration depicted in FIG. 6 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 6, a transistor 640 may include a gate 622 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 640 along the source-channel-drain direction, the gate electrode may consist of a U-shaped structure that includes a bottom portion substantially parallel to the surface of the die substrate 602 and two sidewall portions that are substantially perpendicular to the top surface of the die substrate 602. In other embodiments, at least one of the metal layers that form the gate electrode may simply be a planar layer that is substantially parallel to the top surface of the die substrate 602 and does not include sidewall portions substantially perpendicular to the top surface of the die substrate 602. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 620 may be formed within the die substrate 602 adjacent to the gate 622 of individual transistors 640. The S/D regions 620 may be formed using an implantation/diffusion process or an etching/deposition process, for example. In the former process, dopants such as boron, aluminum, antimony, phosphorous, or arsenic may be ion-implanted into the die substrate 602 to form the S/D regions 620. An annealing process that activates the dopants and causes them to diffuse farther into the die substrate 602 may follow the ion-implantation process. In the latter process, the die substrate 602 may first be etched to form recesses at the locations of the S/D regions 620. An epitaxial deposition process may then be carried out to fill the recesses with material that is used to fabricate the S/D regions 620. In some implementations, the S/D regions 620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 620 may be formed using one or more alternate semiconductor materials such as germanium or a group III-V material or alloy. In further embodiments, one or more layers of metal and/or metal alloys may be used to form the S/D regions 620.

Electrical signals, such as power and/or input/output (I/O) signals, may be routed to and/or from the devices (e.g., transistors 640) of the device layer 604 through one or more interconnect layers disposed on the device layer 604 (illustrated in FIG. 6 as interconnect layers 606-610). For example, electrically conductive features of the device layer 604 (e.g., the gate 622 and the S/D contacts 624) may be electrically coupled with the interconnect structures 628 of the interconnect layers 606-610. The one or more interconnect layers 606-610 may form a metallization stack (also referred to as an “ILD stack”) 619 of the integrated circuit device 600.

The interconnect structures 628 may be arranged within the interconnect layers 606-610 to route electrical signals according to a wide variety of designs; in particular, the arrangement is not limited to the particular configuration of interconnect structures 628 depicted in FIG. 6. Although a particular number of interconnect layers 606-610 is depicted in FIG. 6, embodiments of the present disclosure include integrated circuit devices having more or fewer interconnect layers than depicted.

In some embodiments, the interconnect structures 628 may include lines 628a and/or vias 628b filled with an electrically conductive material such as a metal. The lines 628a may be arranged to route electrical signals in a direction of a plane that is substantially parallel with a surface of the die substrate 602 upon which the device layer 604 is formed. For example, the lines 628a may route electrical signals in a direction in and out of the page and/or in a direction across the page from the perspective of FIG. 6. The vias 628b may be arranged to route electrical signals in a direction of a plane that is substantially perpendicular to the surface of the die substrate 602 upon which the device layer 604 is formed. In some embodiments, the vias 628b may electrically couple lines 628a of different interconnect layers 606-610 together.

The interconnect layers 606-610 may include a dielectric material 626 disposed between the interconnect structures 628, as shown in FIG. 6. In some embodiments, dielectric material 626 disposed between the interconnect structures 628 in different ones of the interconnect layers 606-610 may have different compositions; in other embodiments, the composition of the dielectric material 626 between different interconnect layers 606-610 may be the same. The device layer 604 may include a dielectric material 626 disposed between the transistors 640 and a bottom layer of the metallization stack as well. The dielectric material 626 included in the device layer 604 may have a different composition than the dielectric material 626 included in the interconnect layers 606-610; in other embodiments, the composition of the dielectric material 626 in the device layer 604 may be the same as a dielectric material 626 included in any one of the interconnect layers 606-610.

A first interconnect layer 606 (referred to as Metal 1 or “M1”) may be formed directly on the device layer 604. In some embodiments, the first interconnect layer 606 may include lines 628a and/or vias 628b, as shown. The lines 628a of the first interconnect layer 606 may be coupled with contacts (e.g., the S/D contacts 624) of the device layer 604. The vias 628b of the first interconnect layer 606 may be coupled with the lines 628a of a second interconnect layer 608.

The second interconnect layer 608 (referred to as Metal 2 or “M2”) may be formed directly on the first interconnect layer 606. In some embodiments, the second interconnect layer 608 may include via 628b to couple the lines 628 of the second interconnect layer 608 with the lines 628a of a third interconnect layer 610. Although the lines 628a and the vias 628b are structurally delineated with a line within individual interconnect layers for the sake of clarity, the lines 628a and the vias 628b may be structurally and/or materially contiguous (e.g., simultaneously filled during a dual-damascene process) in some embodiments.

The third interconnect layer 610 (referred to as Metal 3 or “M3”) (and additional interconnect layers, as desired) may be formed in succession on the second interconnect layer 608 according to similar techniques and configurations described in connection with the second interconnect layer 608 or the first interconnect layer 606. In some embodiments, the interconnect layers that are “higher up” in the metallization stack 619 in the integrated circuit device 600 (i.e., farther away from the device layer 604) may be thicker that the interconnect layers that are lower in the metallization stack 619, with lines 628a and vias 628b in the higher interconnect layers being thicker than those in the lower interconnect layers.

The integrated circuit device 600 may include a solder resist material 634 (e.g., polyimide or similar material) and one or more conductive contacts 636 formed on the interconnect layers 606-610. In FIG. 6, the conductive contacts 636 are illustrated as taking the form of bond pads. The conductive contacts 636 may be electrically coupled with the interconnect structures 628 and configured to route the electrical signals of the transistor(s) 640 to external devices. For example, solder bonds may be formed on the one or more conductive contacts 636 to mechanically and/or electrically couple an integrated circuit die including the integrated circuit device 600 with another component (e.g., a printed circuit board). The integrated circuit device 600 may include additional or alternate structures to route the electrical signals from the interconnect layers 606-610; for example, the conductive contacts 636 may include other analogous features (e.g., posts) that route the electrical signals to external components.

In some embodiments in which the integrated circuit device 600 is a double-sided die, the integrated circuit device 600 may include another metallization stack (not shown) on the opposite side of the device layer(s) 604. This metallization stack may include multiple interconnect layers as discussed above with reference to the interconnect layers 606-610, to provide conductive pathways (e.g., including conductive lines and vias) between the device layer(s) 604 and additional conductive contacts (not shown) on the opposite side of the integrated circuit device 600 from the conductive contacts 636.

In other embodiments in which the integrated circuit device 600 is a double-sided die, the integrated circuit device 600 may include one or more through silicon vias (TSVs) through the die substrate 602; these TSVs may make contact with the device layer(s) 604, and may provide conductive pathways between the device layer(s) 604 and additional conductive contacts (not shown) on the opposite side of the integrated circuit device 600 from the conductive contacts 636. In some embodiments, TSVs extending through the substrate can be used for routing power and ground signals from conductive contacts on the opposite side of the integrated circuit device 600 from the conductive contacts 636 to the transistors 640 and any other components integrated into the die 600, and the metallization stack 619 can be used to route I/O signals from the conductive contacts 636 to transistors 640 and any other components integrated into the die 600.

Multiple integrated circuit devices 600 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

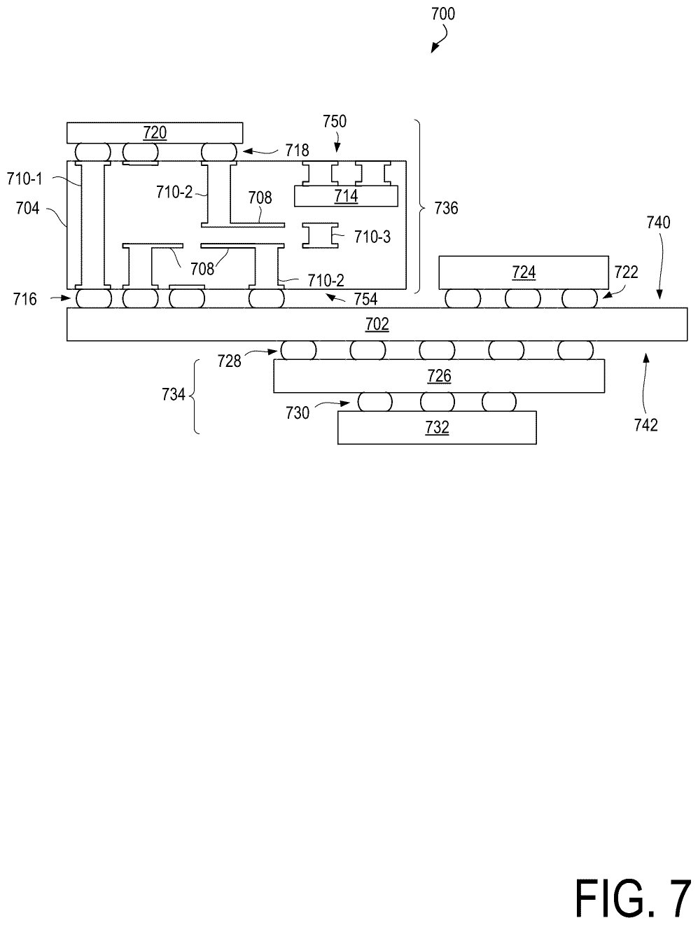

FIG. 7 is a cross-sectional side view of an integrated circuit device assembly 700 that may include any of the embodiments disclosed herein. The integrated circuit device assembly 700 includes a number of components disposed on a circuit board 702 (which may be a motherboard, system board, mainboard, etc.). The integrated circuit device assembly 700 includes components disposed on a first face 740 of the circuit board 702 and an opposing second face 742 of the circuit board 702; generally, components may be disposed on one or both faces 740 and 742.

In some embodiments, the circuit board 702 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 702. In other embodiments, the circuit board 702 may be a non-PCB substrate. The integrated circuit device assembly 700 illustrated in FIG. 7 includes a package-on-interposer structure 736 coupled to the first face 740 of the circuit board 702 by coupling components 716. The coupling components 716 may electrically and mechanically couple the package-on-interposer structure 736 to the circuit board 702, and may include solder balls (as shown in FIG. 7), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 736 may include an integrated circuit component 720 coupled to an interposer 704 by coupling components 718. The coupling components 718 may take any suitable form for the application, such as the forms discussed above with reference to the coupling components 716. Although a single integrated circuit component 720 is shown in FIG. 7, multiple integrated circuit components may be coupled to the interposer 704; indeed, additional interposers may be coupled to the interposer 704. The interposer 704 may provide an intervening substrate used to bridge the circuit board 702 and the integrated circuit component 720.

The integrated circuit component 720 may be a packaged or unpacked integrated circuit product that includes one or more integrated circuit dies (e.g., the die 502 of FIG. 5, the integrated circuit device 600 of FIG. 6) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 720, a single monolithic integrated circuit die comprises solder bumps attached to contacts on the die. The solder bumps allow the die to be directly attached to the interposer 704. The integrated circuit component 720 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 720 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 720 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 720 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 704 may spread connections to a wider pitch or reroute a connection to a different connection. For example, the interposer 704 may couple the integrated circuit component 720 to a set of ball grid array (BGA) conductive contacts of the coupling components 716 for coupling to the circuit board 702. In the embodiment illustrated in FIG. 7, the integrated circuit component 720 and the circuit board 702 are attached to opposing sides of the interposer 704; in other embodiments, the integrated circuit component 720 and the circuit board 702 may be attached to a same side of the interposer 704. In some embodiments, three or more components may be interconnected by way of the interposer 704.

In some embodiments, the interposer 704 may be formed as a PCB, including multiple metal layers separated from one another by layers of dielectric material and interconnected by electrically conductive vias. In some embodiments, the interposer 704 may be formed of an epoxy resin, a fiberglass-reinforced epoxy resin, an epoxy resin with inorganic fillers, a ceramic material, or a polymer material such as polyimide. In some embodiments, the interposer 704 may be formed of alternate rigid or flexible materials that may include the same materials described above for use in a semiconductor substrate, such as silicon, germanium, and other group III-V and group IV materials. The interposer 704 may include metal interconnects 708 and vias 710, including but not limited to through hole vias 710-1 (that extend from a first face 750 of the interposer 704 to a second face 754 of the interposer 704), blind vias 710-2 (that extend from the first or second faces 750 or 754 of the interposer 704 to an internal metal layer), and buried vias 710-3 (that connect internal metal layers).

In some embodiments, the interposer 704 can comprise a silicon interposer. Through silicon vias (TSV) extending through the silicon interposer can connect connections on a first face of a silicon interposer to an opposing second face of the silicon interposer. In some embodiments, an interposer 704 comprising a silicon interposer can further comprise one or more routing layers to route connections on a first face of the interposer 704 to an opposing second face of the interposer 704.

The interposer 704 may further include embedded devices 714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 704. The package-on-interposer structure 736 may take the form of any of the package-on-interposer structures known in the art. In embodiments where the interposer is a non-printed circuit board

The integrated circuit device assembly 700 may include an integrated circuit component 724 coupled to the first face 740 of the circuit board 702 by coupling components 722. The coupling components 722 may take the form of any of the embodiments discussed above with reference to the coupling components 716, and the integrated circuit component 724 may take the form of any of the embodiments discussed above with reference to the integrated circuit component 720.

The integrated circuit device assembly 700 illustrated in FIG. 7 includes a package-on-package structure 734 coupled to the second face 742 of the circuit board 702 by coupling components 728. The package-on-package structure 734 may include an integrated circuit component 726 and an integrated circuit component 732 coupled together by coupling components 730 such that the integrated circuit component 726 is disposed between the circuit board 702 and the integrated circuit component 732. The coupling components 728 and 730 may take the form of any of the embodiments of the coupling components 716 discussed above, and the integrated circuit components 726 and 732 may take the form of any of the embodiments of the integrated circuit component 720 discussed above. The package-on-package structure 734 may be configured in accordance with any of the package-on-package structures known in the art.

FIG. 8 is a block diagram of an example electrical device 800 that may include one or more of the embodiments disclosed herein. For example, any suitable ones of the components of the electrical device 800 may include one or more of the integrated circuit device assemblies 700, integrated circuit components 720, integrated circuit devices 600, or integrated circuit dies 502 disclosed herein. A number of components are illustrated in FIG. 8 as included in the electrical device 800, but any one or more of these components may be omitted or duplicated, as suitable for the application. In some embodiments, some or all of the components included in the electrical device 800 may be attached to one or more motherboards mainboards, or system boards. In some embodiments, one or more of these components are fabricated onto a single system-on-a-chip (SoC) die.

Additionally, in various embodiments, the electrical device 800 may not include one or more of the components illustrated in FIG. 8, but the electrical device 800 may include interface circuitry for coupling to the one or more components. For example, the electrical device 800 may not include a display device 806, but may include display device interface circuitry (e.g., a connector and driver circuitry) to which a display device 806 may be coupled. In another set of examples, the electrical device 800 may not include an audio input device 824 or an audio output device 808, but may include audio input or output device interface circuitry (e.g., connectors and supporting circuitry) to which an audio input device 824 or audio output device 808 may be coupled.

The electrical device 800 may include one or more processor units 802 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 802 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 800 may include a memory 804, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 804 may include memory that is located on the same integrated circuit die as the processor unit 802. This memory may be used as cache memory (e.g., Level 1 (L1), Level 2 (L2), Level 3 (L3), Level 4 (LA), Last Level Cache (LLC)) and may include embedded dynamic random access memory (eDRAM) or spin transfer torque magnetic random access memory (STT-MRAM).

In some embodiments, the electrical device 800 can comprise one or more processor units 802 that are heterogeneous or asymmetric to another processor unit 802 in the electrical device 800. There can be a variety of differences between the processing units 802 in a system in terms of a spectrum of metrics of merit including architectural, microarchitectural, thermal, power consumption characteristics, and the like. These differences can effectively manifest themselves as asymmetry and heterogeneity among the processor units 802 in the electrical device 800.

In some embodiments, the electrical device 800 may include a communication component 812 (e.g., one or more communication components). For example, the communication component 812 can manage wireless communications for the transfer of data to and from the electrical device 800. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 812 may operate in accordance with other wireless protocols in other embodiments. The electrical device 800 may include an antenna 822 to facilitate wireless communications and/or to receive other wireless communications (such as AM or FM radio transmissions).

In some embodiments, the communication component 812 may manage wired communications, such as electrical, optical, or any other suitable communication protocols (e.g., IEEE 802.3 Ethernet standards). As noted above, the communication component 812 may include multiple communication components. For instance, a first communication component 812 may be dedicated to shorter-range wireless communications such as Wi-Fi or Bluetooth, and a second communication component 812 may be dedicated to longer-range wireless communications such as global positioning system (GPS), EDGE, GPRS, CDMA, WiMAX, LTE, EV-DO, or others. In some embodiments, a first communication component 812 may be dedicated to wireless communications, and a second communication component 812 may be dedicated to wired communications.

The electrical device 800 may include battery/power circuitry 814. The battery/power circuitry 814 may include one or more energy storage devices (e.g., batteries or capacitors) and/or circuitry for coupling components of the electrical device 800 to an energy source separate from the electrical device 800 (e.g., AC line power).

The electrical device 800 may include a display device 806 (or corresponding interface circuitry, as discussed above). The display device 806 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 800 may include an audio output device 808 (or corresponding interface circuitry, as discussed above). The audio output device 808 may include any embedded or wired or wirelessly connected external device that generates an audible indicator, such speakers, headsets, or earbuds.

The electrical device 800 may include an audio input device 824 (or corresponding interface circuitry, as discussed above). The audio input device 824 may include any embedded or wired or wirelessly connected device that generates a signal representative of a sound, such as microphones, microphone arrays, or digital instruments (e.g., instruments having a musical instrument digital interface (MIDI) output). The electrical device 800 may include a Global Navigation Satellite System (GNSS) device 818 (or corresponding interface circuitry, as discussed above), such as a Global Positioning System (GPS) device. The GNSS device 818 may be in communication with a satellite-based system and may determine a geolocation of the electrical device 800 based on information received from one or more GNSS satellites, as known in the art.

The electrical device 800 may include an other output device 810 (or corresponding interface circuitry, as discussed above). Examples of the other output device 810 may include an audio codec, a video codec, a printer, a wired or wireless transmitter for providing information to other devices, or an additional storage device.

The electrical device 800 may include another input device 820 (or corresponding interface circuitry, as discussed above). Examples of the other input device 820 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 800 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 800 may be any other electronic device that processes data. In some embodiments, the electrical device 800 may comprise multiple discrete physical components. Given the range of devices that the electrical device 800 can be manifested as in various embodiments, in some embodiments, the electrical device 800 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.
Example 1 is a transistor device comprising: a perovskite semiconductor material layer; a first perovskite conductor on a first end of the perovskite semiconductor material layer; a second perovskite conductor on a second end of the perovskite semiconductor material layer opposite the first end; a perovskite dielectric material layer on the perovskite semiconductor material layer between the first perovskite conductor and the second perovskite conductor; a perovskite ferroelectric material layer on the dielectric material layer; and a third perovskite conductor on the perovskite ferroelectric material layer.
Example 2 includes the subject matter of Example 1, further comprising a fourth perovskite conductor, wherein the perovskite semiconductor material layer is on the fourth perovskite conductor and the fourth perovskite conductor is connected to the third perovskite conductor.
Example 3 includes the subject matter of Example 1 or 2, further comprising a fifth perovskite conductor between the perovskite dielectric material layer and the ferroelectric material layer.
Example 4 includes the subject matter of any one of Examples 1-3, wherein the perovskite semiconductor material layer comprises Barium, Tin, Oxygen, and at least one of Lanthanum, Neodymium, Caesium, Yttrium, and Vanadium.
Example 5 includes the subject matter of Example 4, wherein the perovskite semiconductor material layer further comprises Strontium.
Example 6 includes the subject matter of any one of Examples 1-3, wherein the perovskite semiconductor material layer comprises Strontium, Titanium, Oxygen, and at least one of Lanthanum, Neodymium, Caesium, Yttrium, and Vanadium.
Example 7 includes the subject matter of any one of Examples 1-6, wherein the first perovskite conductor, the second perovskite conductor, and the third perovskite conductor comprise Strontium, Ruthenium, and Oxygen.
Example 8 includes the subject matter of Example 7, wherein the first perovskite conductor and the second perovskite conductor further comprises Barium.
Example 9 includes the subject matter of any one of Examples 1-8, wherein the perovskite ferroelectric material layer comprises Barium, Titanium, and Oxygen.
Example 10 includes the subject matter of Example 9, wherein the perovskite ferroelectric material layer further comprises one or more of Zirconium, Calcium, Strontium, and Hafnium.
Example 11 includes the subject matter of any one of Examples 1-10, wherein the perovskite dielectric material layer comprises Oxygen, one of Barium or Strontium, and one of Tin, Titanium, Hafnium, or Zirconium.
Example 12 is a transistor device comprising: a conductive layer; a perovskite ferroelectric material layer on the conductive layer; a dielectric material layer on the perovskite ferroelectric material layer; a two-dimensional transition metal dichalcogenide (2D TMD) material layer on the dielectric material layer; a first semiconductor material on a first end of the 2D TMD material layer; and a second semiconductor material on a second end of the 2D TMD material layer opposite the first end.
Example 13 includes the subject matter of Example 12, wherein the 2D TMD material comprises one of Molybdenum, Tungsten, and Niobium, and one of Sulfur, Selenium, and Tellurium.
Example 14 includes the subject matter of any one of Examples 12-13, wherein the perovskite ferroelectric material layer comprises Barium, Titanium, and Oxygen.
Example 15 includes the subject matter of Example 14, wherein the perovskite ferroelectric material layer further comprises one or more of Zirconium, Calcium, Strontium, and Hafnium.
Example 16 includes the subject matter of any one of Examples 12-15, wherein the first semiconductor material and the second semiconductor material comprise Barium, Tin, Oxygen, and at least one of Lanthanum, Neodymium, Caesium, Yttrium, and Vanadium.
Example 17 includes the subject matter of Example 16, wherein the first semiconductor material and the second semiconductor material further comprise Barium.
Example 18 includes the subject matter of any one of Examples 12-15, wherein the first semiconductor material and the second semiconductor material comprise Strontium, Titanium, Oxygen, and at least one of Lanthanum, Neodymium, Caesium, Yttrium, and Vanadium.
Example 19 includes the subject matter of any one of Examples 12-15, wherein the first semiconductor material and the second semiconductor material comprise a 2D TMD material.
Example 20 includes the subject matter of Example 19, wherein the first semiconductor material and the second semiconductor material comprise one of Molybdenum, Tungsten, and Niobium, and one of Sulfur, Selenium, and Tellurium
Example 21 includes the subject matter of any one of Examples 12-20, wherein the conductive layer comprises Strontium, Ruthenium, and Oxygen.
Example 22 includes the subject matter of any one of Examples 12-21, wherein the dielectric material layer comprises Oxygen and one of Tantalum, Hafnium, Magnesium, Aluminum, and Germanium.
Example 23 is a transistor device comprising: a first conductive layer; a perovskite ferroelectric material layer on the first conductive layer; a second conductive layer on the perovskite ferroelectric material layer; a dielectric material layer on the second conductive layer; a two-dimensional transition metal dichalcogenide (2D TMD) material layer on the dielectric material layer; a first semiconductor material on a first end of the 2D TMD material layer; and a second semiconductor material on a second end of the 2D TMD material layer opposite the first end.
Example 24 includes the subject matter of Example 23, wherein the 2D TMD material comprises one of Molybdenum, Tungsten, and Niobium, and one of Sulfur, Selenium, and Tellurium.
Example 25 includes the subject matter of any one of Examples 23-24, wherein the perovskite ferroelectric material layer comprises Barium, Titanium, and Oxygen.
Example 26 includes the subject matter of Example 25, wherein the perovskite ferroelectric material layer further comprises one or more of Zirconium, Calcium, Strontium, and Hafnium.
Example 27 includes the subject matter of any one of Examples 23-26, wherein the first semiconductor material and the second semiconductor material comprise Barium, Tin, Oxygen, and at least one of Lanthanum, Neodymium, Caesium, Yttrium, and Vanadium.
Example 28 includes the subject matter of Example 27, wherein the first semiconductor material and the second semiconductor material further comprise Barium.
Example 29 includes the subject matter of any one of Examples 23-26, wherein the first semiconductor material and the second semiconductor material comprise Strontium, Titanium, Oxygen, and at least one of Lanthanum, Neodymium, Caesium, Yttrium, and Vanadium.
Example 30 includes the subject matter of any one of Examples 23-26, wherein the first semiconductor material and the second semiconductor material comprise a 2D TMD material.
Example 31 includes the subject matter of Example 30, wherein the first semiconductor material and the second semiconductor material comprise one of Molybdenum, Tungsten, and Niobium, and one of Sulfur, Selenium, and Tellurium.
Example 32 includes the subject matter of any one of Examples 23-27, wherein the first conductive layer and the second conductive layer comprise Strontium, Ruthenium, and Oxygen.
Example 33 includes the subject matter of any one of Examples 23-28, wherein the dielectric material layer comprises Oxygen and one of Tantalum, Hafnium, Magnesium, Aluminum, and Germanium.
Example A1 is a transistor device comprising a first layer comprising a perovskite semiconductor material; a first conductor on a first end of the perovskite semiconductor material layer, the first conductor comprising a conductive perovskite material; a second conductor on a second end of the perovskite semiconductor material layer opposite the first end, the second conductor comprising a conductive perovskite material; a second layer on the first layer between the first conductor and the second conductor, the second layer comprising a dielectric perovskite material; a third layer on the second material layer, the third layer comprising a perovskite ferroelectric material; and a third conductor on the third layer, the third conductor comprising a conductive perovskite material.
Example A2 includes the subject matter of Example 1, further comprising a fourth conductor comprising a conductive perovskite material, wherein the first layer is on the fourth conductor and the fourth conductor is connected to the third conductor.
Example A3 includes the subject matter of Example A1 or A2, further comprising a fifth conductor between the second layer and the third layer, the fifth conductor comprising a conductive perovskite material.
Example A4 includes the subject matter of any one of Examples A1-A3, wherein the first layer comprises Barium, Tin, Oxygen, and at least one of Lanthanum, Neodymium, Caesium, Yttrium, and Vanadium.
Example A5 includes the subject matter of Example A4, wherein the first layer further comprises Strontium.
Example A6 includes the subject matter of any one of Examples A1-A3, wherein the first layer comprises Strontium, Titanium, Oxygen, and at least one of Lanthanum, Neodymium, Caesium, Yttrium, and Vanadium.
Example A7 includes the subject matter of any one of Examples A1-A6, wherein the first conductor, the second conductor, and the third conductor comprise Strontium, Ruthenium, and Oxygen.
Example A8 includes the subject matter of Example A7, wherein the first conductor and the second conductor further comprises Barium.
Example A9 includes the subject matter of any one of Examples A1-A8, wherein the third layer comprises Barium, Titanium, and Oxygen.
Example A10 includes the subject matter of Example A9, wherein the second layer further comprises one or more of Zirconium, Calcium, Strontium, and Hafnium.
Example A11 includes the subject matter of any one of Examples A1-A10, wherein the second layer comprises Oxygen, one of Barium or Strontium, and one of Tin, Titanium, Hafnium, or Zirconium.
Example A12 is a transistor device comprising: a first layer comprising a conductive material; a second layer on the first layer, the second layer comprising a perovskite ferroelectric material; a third layer on the second layer, the third layer comprising a dielectric material; a fourth layer on the third layer, the fourth layer comprising a two-dimensional transition metal dichalcogenide (2D TMD) material; a first semiconductor material on a first end of the 2D TMD material layer; and a second semiconductor material on a second end of the 2D TMD material layer opposite the first end.
Example A13 includes the subject matter of Example A12, wherein the fourth layer comprises one of Molybdenum, Tungsten, and Niobium, and one of Sulfur, Selenium, and Tellurium.
Example A14 includes the subject matter of any one of Examples A12-A13, wherein the second layer comprises Barium, Titanium, and Oxygen.
Example A15 includes the subject matter of Example A14, wherein the second layer further comprises one or more of Zirconium, Calcium, Strontium, and Hafnium.
Example A16 includes the subject matter of any one of Examples A12-A15, wherein the first semiconductor material and the second semiconductor material comprise a perovskite material comprising Barium, Tin, Oxygen, and at least one of Lanthanum, Neodymium, Caesium, Yttrium, and Vanadium.
Example A17 includes the subject matter of Example A16, wherein the first semiconductor material and the second semiconductor material further comprise Barium.
Example A18 includes the subject matter of any one of Examples A12-A15, wherein the first semiconductor material and the second semiconductor material comprise a perovskite material comprising Strontium, Titanium, Oxygen, and at least one of Lanthanum, Neodymium, Caesium, Yttrium, and Vanadium.
Example A19 includes the subject matter of any one of Examples A12-A15, wherein the first semiconductor material and the second semiconductor material comprise a 2D TMD material.
Example A20 includes the subject matter of Example A19, wherein the first semiconductor material and the second semiconductor material comprise one of Molybdenum, Tungsten, and Niobium, and one of Sulfur, Selenium, and Tellurium
Example A21 includes the subject matter of any one of Examples A12-A20, wherein the first layer comprises Strontium, Ruthenium, and Oxygen.
Example A22 includes the subject matter of any one of Examples A12-A21, wherein the third layer comprises Oxygen and one of Tantalum, Hafnium, Magnesium, Aluminum, and Germanium.
Example A23 is a transistor device comprising: a first layer comprising a conductive material; a second layer on the first layer, the second layer comprising a perovskite ferroelectric material; a third layer on the second layer, the third layer comprising a conductive material; a fourth layer on the third layer, the fourth layer comprising a dielectric material; a fifth layer on the fourth layer, the fifth layer comprising a two-dimensional transition metal dichalcogenide (2D TMD) material; a first semiconductor material on a first end of the fifth layer; and a second semiconductor material on a second end of the fifth layer opposite the first end.
Example A24 includes the subject matter of Example A23, wherein the fifth layer comprises one of Molybdenum, Tungsten, and Niobium, and one of Sulfur, Selenium, and Tellurium.
Example A25 includes the subject matter of any one of Examples A23-A24, wherein the second layer comprises Barium, Titanium, and Oxygen.
Example A26 includes the subject matter of Example A25, wherein the second layer further comprises one or more of Zirconium, Calcium, Strontium, and Hafnium.
Example A27 includes the subject matter of any one of Examples A23-A26, wherein the first semiconductor material and the second semiconductor material comprise a perovskite material comprising Barium, Tin, Oxygen, and at least one of Lanthanum, Neodymium, Caesium, Yttrium, and Vanadium.
Example A28 includes the subject matter of Example A27, wherein the first semiconductor material and the second semiconductor material further comprise Barium.
Example A29 includes the subject matter of any one of Examples A23-A26, wherein the first semiconductor material and the second semiconductor material comprise a perovskite material comprising Strontium, Titanium, Oxygen, and at least one of Lanthanum, Neodymium, Caesium, Yttrium, and Vanadium.
Example A30 includes the subject matter of any one of Examples A23-A26, wherein the first semiconductor material and the second semiconductor material comprise a 2D TMD material.
Example A31 includes the subject matter of Example A30, wherein the first semiconductor material and the second semiconductor material comprise one of Molybdenum, Tungsten, and Niobium, and one of Sulfur, Selenium, and Tellurium.
Example A32 includes the subject matter of any one of Examples A23-A27, wherein the first layer and the third layer comprise Strontium, Ruthenium, and Oxygen.
Example A33 includes the subject matter of any one of Examples A23-A28, wherein the fourth layer comprises Oxygen and one of Tantalum, Hafnium, Magnesium, Aluminum, and Germanium.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

In various embodiments, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

In various embodiments, the term “adjacent” refers to layers or components that are in physical contact with each other. That is, there is no layer or component between the stated adjacent layers or components. For example, a layer X that is adjacent to a layer Y refers to a layer that is in physical contact with layer Y.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. A transistor device comprising:
a first layer comprising a perovskite semiconductor material;
a first conductor on a first end of the perovskite semiconductor material layer, the first conductor comprising a conductive perovskite material;
a second conductor on a second end of the perovskite semiconductor material layer opposite the first end, the second conductor comprising a conductive perovskite material;
a second layer on the first layer between the first conductor and the second conductor, the second layer comprising a dielectric perovskite material;
a third layer on the second material layer, the third layer comprising a perovskite ferroelectric material; and
a third conductor on the third layer, the third conductor comprising a conductive perovskite material.

2. The device of claim 1, further comprising a fourth conductor comprising a conductive perovskite material, wherein the first layer is on the fourth conductor and the fourth conductor is connected to the third conductor.

3. The device of claim 1, further comprising a fifth conductor between the second layer and the third layer, the fifth conductor comprising a conductive perovskite material.

4. The device of claim 1, wherein the first layer comprises Barium, Tin, Oxygen, and at least one of Lanthanum, Neodymium, Caesium, Yttrium, and Vanadium.

5. The device of claim 1, wherein the first layer comprises Strontium, Titanium, Oxygen, and at least one of Lanthanum, Neodymium, Caesium, Yttrium, and Vanadium.

6. The device of claim 1, wherein the first conductor, the second conductor, and the third conductor comprise Strontium, Ruthenium, and Oxygen.

7. The device of claim 1, wherein the third layer comprises Barium, Titanium, and Oxygen.

8. The device of claim 1, wherein the second layer comprises Oxygen, one of Barium or Strontium, and one of Tin, Titanium, Hafnium, or Zirconium.

9. A transistor device comprising:
a first layer comprising a conductive material;
a second layer on the first layer, the second layer comprising a perovskite ferroelectric material;
a third layer on the second layer, the third layer comprising a dielectric material;
a fourth layer on the third layer, the fourth layer comprising a two-dimensional transition metal dichalcogenide (2D TMD) material;
a first semiconductor material on a first end of the 2D TMD material layer; and
a second semiconductor material on a second end of the 2D TMD material layer opposite the first end.

10. The device of claim 9, wherein the fourth layer comprises one of Molybdenum, Tungsten, and Niobium, and one of Sulfur, Selenium, and Tellurium.

11. The device of claim 9, wherein the second layer comprises Barium, Titanium, and Oxygen.

12. The device of claim 9, wherein the first semiconductor material and the second semiconductor material comprise perovskite materials.

13. The device of claim 12, wherein the first semiconductor material and the second semiconductor material comprise Barium, Tin, Oxygen, and at least one of Lanthanum, Neodymium, Caesium, Yttrium, and Vanadium.

14. The device of claim 12, wherein the first semiconductor material and the second semiconductor material comprise Strontium, Titanium, Oxygen, and at least one of Lanthanum, Neodymium, Caesium, Yttrium, and Vanadium.

15. The device of claim 9, wherein the first semiconductor material and the second semiconductor material comprise a 2D TMD material.

16. The device of claim 15, wherein the first semiconductor material and the second semiconductor material comprise one of Molybdenum, Tungsten, and Niobium, and one of Sulfur, Selenium, and Tellurium.

17. A transistor device comprising:
a first layer comprising a conductive material;
a second layer on the first layer, the second layer comprising a perovskite ferroelectric material;
a third layer on the second layer, the third layer comprising a conductive material;
a fourth layer on the third layer, the fourth layer comprising a dielectric material;
a fifth layer on the fourth layer, the fifth layer comprising a two-dimensional transition metal dichalcogenide (2D TMD) material;
a first semiconductor material on a first end of the fifth layer; and
a second semiconductor material on a second end of the fifth layer opposite the first end.

18. The device of claim 17, wherein the fifth layer comprises one of Molybdenum, Tungsten, and Niobium, and one of Sulfur, Selenium, and Tellurium.

19. The device of claim 17, wherein the first semiconductor material and the second semiconductor material comprise perovskite materials.

20. The device of claim 17, wherein the first semiconductor material and the second semiconductor material comprise a 2D TMD material.
